(19) United States
(12) Patent Application Publication
(10) Pub. No.: US 2009/0316350 A1
(43) Pub. Date: Dec. 24, 2009

(54) EXTERNAL HARD DISK BOX HAVING A COVER-LIFTING MEANS

(76) Inventor: Chien-Da Hu, Jhongli City (TW)

Correspondence Address: NIKOLAI & MERSEREAU, P.A., 900 SECOND AVENUE SOUTH, SUITE 820, MINNEAPOLIS, MN, 55402, US

(21) Appl. No.: 12/143,266

(22) Filed: Jun. 20, 2008

(51) Int. Cl. H05K 5/00

(52) U.S. Cl. 361/679.33

(57) ABSTRACT

An external hard disk box having a cover-lifting means includes a hollow base and a cover. The cover is pivotally connected to the base in a liftable and closable manner. The cover is provided with a hard disk accommodating portion for accommodating a hard disk. When the cover is lifted, the hard disk is elevated along with the cover, so that the user can take out the hard disk easily. When the cover is covered, the cover is locked onto the base. Via this arrangement, it is convenient and labor-saving for the user to mount or detach the hard disk.

### BACKGROUND OF THE INVENTION

1. Field of the Invention

The present invention relates to an external hard disk box having a cover-lifting means, and in particular to an external hard disk box having a liftable cover whereby a user can detach a hard disk more easily.

2. Description of Related Art

With the development of information technology, peripheral devices for a computer have become important tools for modern people. With the digitalization of various data, consumers have more demands for storing electronic data. Therefore, the manufactures in this industry develop various storage medium for electronic data. Portable storage medium for electronic data available in the market include floppy disks, optical disks, memory cards, flash memory or the like. Although the floppy disk, the memory card and the flash memory is portable and convenient in storing data, their capacity for storing data is not sufficient and thus their usage is limited.

On the other hand, although the optical disk has a larger storage capacity, it still does not conform to the modern demand. Furthermore, the data can be only recorded on the optical disk by burning, so that it is not convenient to use the optical disk. Thus, a portable external hard disk box is developed in which a hard disk is mounted.

Taiwan Patent Application No. 92220549 published on Nov. 21, 2004 and entitled “Aluminum-extruded external hard disk box assembled by tracks” discloses a conventional external hard disk box, which comprises an aluminum-extruded casing, a back panel, supporting pieces, a bridging plate, rails, a front panel and a hard disk driver. The aluminum-extruded casing is made by extruding aluminum longitudinally and is cut according to a desired length. The inner edge of the casing is provided with troughs and screw slots. The characteristic of this previous application lies in that the rear panel, the supporting pieces, the bridging plate and the symmetrical rails are connected to each other so as to form one unit. The rails allow the hard disk driver to be fixed thereon. The rails are assembled with the troughs in the inner edge of the aluminum-extruded casing, and screws are fitted in the screw slots on the inner edge of the aluminum-extruded casing from the screw holes of the rear panel.

However, when the above-mentioned conventional external hard disk box is used, the screws fixed on the rear panel must be detached first and the rails pulled out. Then, the hard disk can be mounted or detached. Thereafter, the rails are pushed into the aluminum-extruded casing. Finally, the rear panel is locked by screws again, thereby completing the mounting or detaching operation. In the above operation, the user has to utilize a screw driver thereby to detach the rear panel. Therefore, it is inconvenient and time-wasting to use the above conventional hard disk box.

Consequently, because of the above limitation resulting from the technical design of prior art, the inventor strives via real world experience and academic research to develop the present invention, which can effectively improve the limitations described above.

### SUMMARY OF THE INVENTION

The object of the present invention is to provide an external hard disk box having a cover-lifting means, which has a base and a cover that is pivotally connected to the base in a liftable and closable manner. The hard disk is mounted on the cover. Via this arrangement, when the user detaches the hard disk, it is more convenient and labor-saving since the hard disk elevates along with the cover as the cover opens.

In order to achieve the above objects, the present invention provides an external hard disk box having a cover-lifting means, which includes a hollow base and a cover. The cover is pivotally connected to the base in a liftable and closable manner. The cover is provided with a hard disk accommodating portion for accommodating a hard disk. When the cover is lifted, the hard disk is elevated along with the cover, so that it is convenient for the user to take out the hard disk.

The present invention has advantageous features as follows. The cover is pivotally connected to the base in a liftable and closable manner, and the hard disk is mounted on the cover. Thus, when the cover is lifted, the hard disk is elevated along with the cover, so that it is more convenient and labor-saving for the user to detach the hard disk.

In order to further understand the characteristics and technical contents of the present invention, a detailed description relating thereto will be made with reference to the accompanying drawings. However, the drawings are illustrative only, but not used to limit the scope of the present invention.

### BRIEF DESCRIPTION OF THE DRAWINGS

FIG. 1 is an exploded perspective top view showing the external hard disk box having a cover-lifting means of the present invention;

FIG. 2 is an exploded perspective bottom view showing the external hard disk box having a cover-lifting means of the present invention;

FIG. 3 is a perspective view showing the base of the external hard disk box having a cover-lifting means of the present invention;

FIG. 4 is a top view showing the base of the external hard disk box having a cover-lifting means of the present invention;

FIG. 5 is an assembled perspective view showing the external hard disk box having a cover-lifting means of the present invention; and

FIG. 6 is a cross-sectional perspective view showing the external hard disk box having a cover-lifting means of the present invention.

### DETAILED DESCRIPTION OF THE PREFERRED EMBODIMENTS

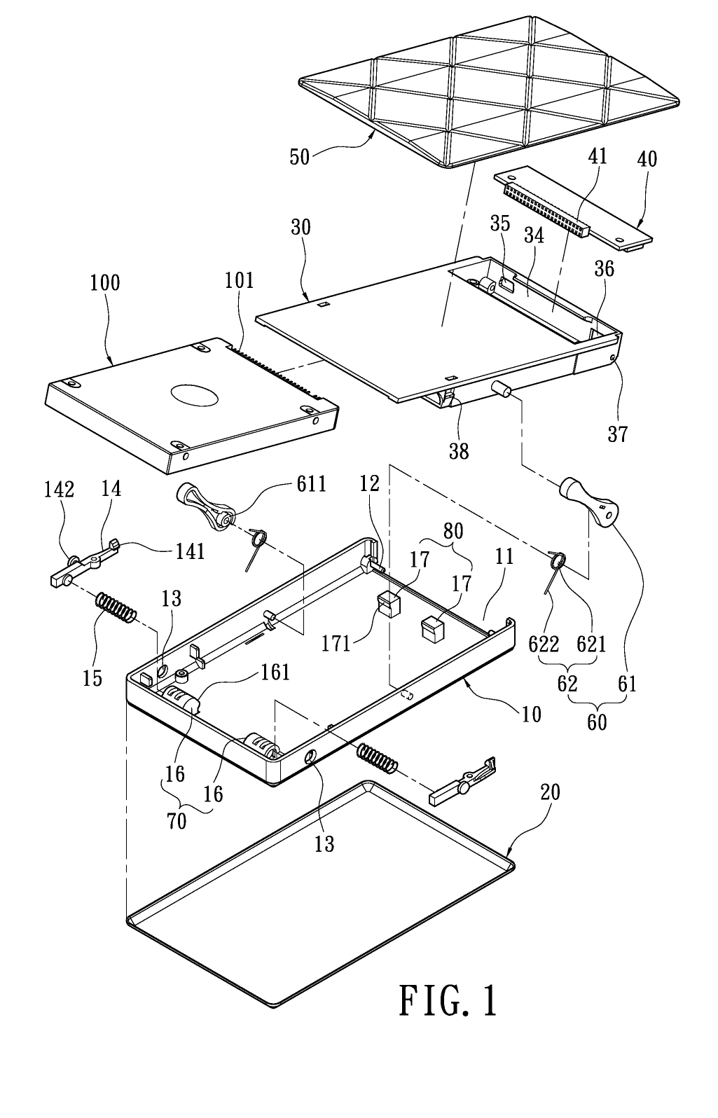

Please refer to FIGS. 1 to 4. The present invention provides an external hard disk box having a cover-lifting means, which includes a base 10, a first casing 20, a cover 30, an adapter circuit board 40, a second casing 50 and a pair of cover-ejecting structures 60.

The base 10 is hollow and the rear end of the base 10 is formed into an opening 11. The base 10 is provided with a pair of first pivoting portions 12 respectively on both inner side walls adjacent to the opening 11 (it should be noted, only one first pivoting portion 12 out of the pair is marked on FIG. 1, since the other first pivoting portion 12 is mostly obscured by the base 10; similarly, for simplicity sake, those objects that come in pair are generally considered as one unit and only has one numeral marked to prevent cluttering). In the present embodiment, the pair of first pivoting portions 12 is a pivotal shaft, but it is not limited thereto. Both sides of the base 10 adjacent to its front end are provided with a through hole 13 respectively.

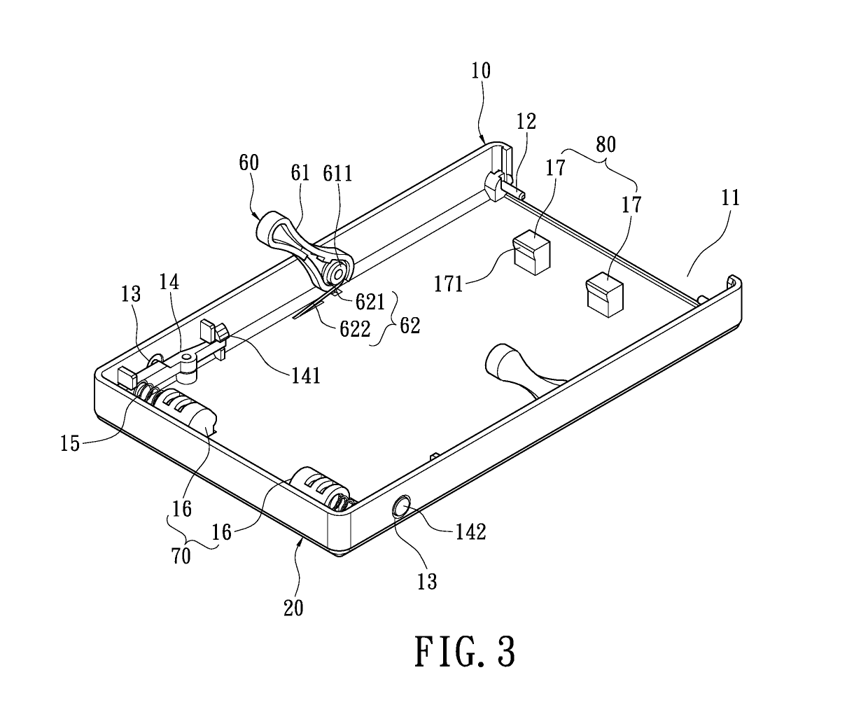

The interior of the base 10 is provided with at least one locking pieces 14 and at least one first elastic elements 15, in this particular embodiment, there are a pair of locking pieces 14 and a pair of first elastic elements 15. The middle portion of each locking piece 14 is pivotally connected to the inside of the cover 10 near its front end (FIG. 3). The below holds true for either of the locking piece 14; one end of the locking piece 14 is provided with a first locking portion 141 and the other end thereof is provided with an operating portion 142. The operating portion 142 extends from the base 10 via the through hole 13, so that the user can exert a force to push the operating portion to move the locking piece 14. The first elastic element 15 abuts against one side of the locking piece 14, thereby providing an elastic restoring force for the locking piece 14.

The first casing 20 is adhered to the outer surface of the base 10 and can be made of different materials (such as metal) than the base 10, thereby changing the external appearance of the base 10 and further enhancing the strength of the base 10.

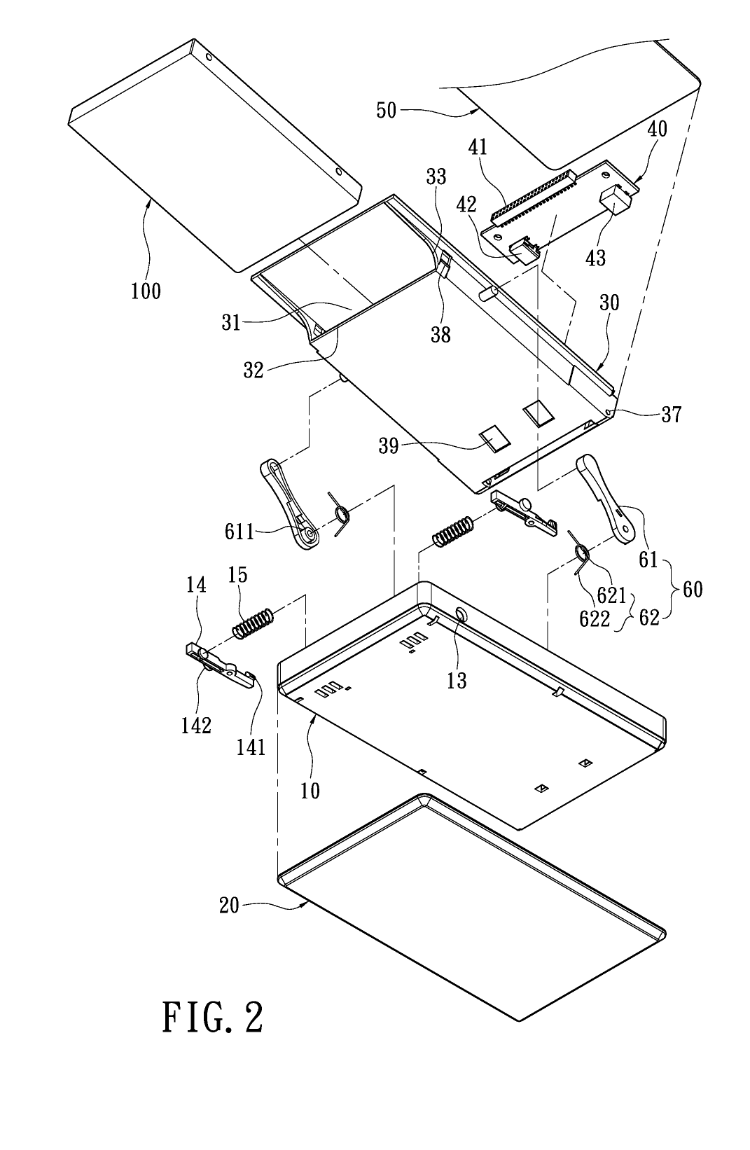

The interior of the cover 30 is provided with a hard disk accommodating portion 31 (FIG. 2) for accommodating a hard disk 100 and preventing the hard disk 100 from falling out of the cover 30. In the present embodiment, the hard disk accommodating portion 31 is an accommodating trough. The accommodating trough is formed by means of recessing inwardly from the front end of the cover 30. The front end of the cover 30 is provided with an insertion hole 32 that is in communication with the hard disk accommodating port 31 (FIG. 2) (“is in communication with” generally means “has opening to” in terms of mechanical structure), so that the user can insert the hard disk 100 into the insertion hole. Both sides of the front end of the cover 30 are provided with a notch 33 respectively, so that a portion of both side surfaces of the hard disk 100 can be exposed to the outside. Thus, the user can grip both sides of the hard disk 100 more easily and can take out the hard disk 100 with less labor. Furthermore, the specification of the hard disk 100 is not limited and can be 2.5″, 3.5″ or the like.

The top surface of the cover 30 near its rear end is recessed inwardly to form an adapter circuit board accommodating portion 34 (FIG. 1). The adapter circuit board accommodating portion 34 is in communication with the hard disk accommodating portion 31. The rear end surface of the cover 30 is provided with a first through hole 35 and a second through hole 36 that are spaced from each other and in communication with the adapter circuit board accommodating portion 34.

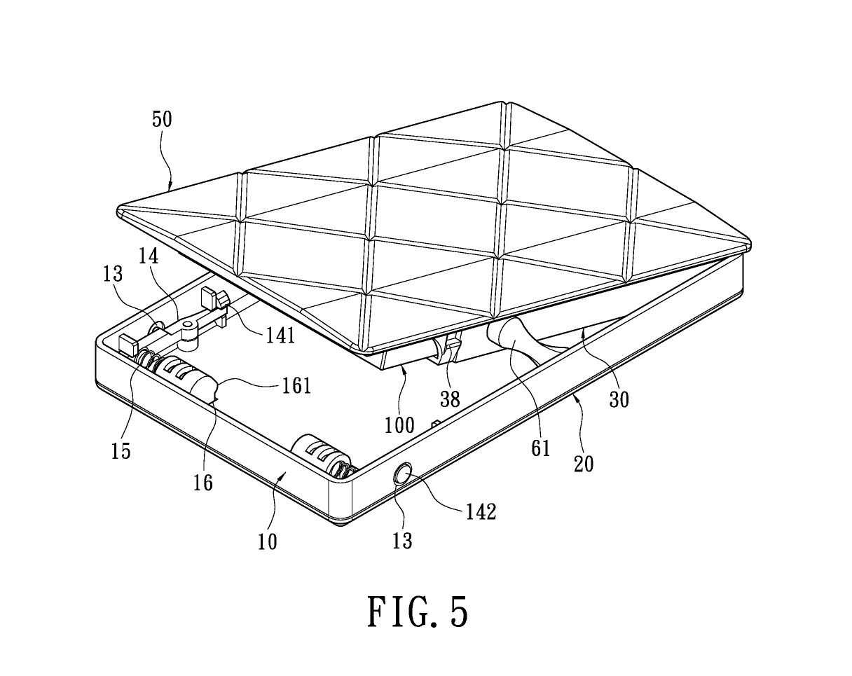

Both sides of the rear end of the cover 30 are provided with a second pivoting portion 37 respectively. In the present embodiment, the second pivoting portion 37 is a pivoting hole. The second pivoting portion 37 is correspondingly connected to the first pivoting portion 12 of the base 10, so that the cover 30 can be pivotally connected to the base 10 in a liftable and closable manner (also refer to FIG. 5). Both sides of the cover 30 protrude outwards to form a second locking portion 38 respectively to correspond to the first locking portion 141 of the locking piece 14.

The adapter circuit board 40 is provided with a hard disk connector 41, an output 42 and a power input 43. The hard disk connector 41 is used to connect to a predetermined connector 101 of the hard disk (FIG. 1), thereby achieving electrical connection. The adapter circuit board 40 is accommodated in the adapter circuit board accommodating portion 34 of the cover 30. The output 42 and the power input 43 correspond to the first through hole 35 and the second through hole 36 respectively.

The second casing 50 is adhered to the outer surface of the cover 30. Further, the surface of the second casing 50 is formed with decorative patterns, thereby increasing the aesthetic feeling thereof.

The pair of cover-ejecting structures 60 is provided between the base 10 and the cover 30 and comprises at least one supporting arms 61 and at least one second elastic elements 62 corresponding to the supporting arms 61; however in this particular embodiment, there are a pair of supporting arms 61 and a pair of second elastic elements 62. The below holds true for either of the supporting arm 61; one end of the supporting arm 61 is fixedly pivotally connected to the base 10 and is provided with a protruding pillar 611. The other end of the supporting arm 61 is movably pivotally connected to the cover 30.

In the present embodiment, the below holds true for either of the cover-ejecting structure 60, the second elastic element 62 is a torsion spring, and it has a central portion 621 and two ends 622 extending obliquely from the central portion 621. The central portion 621 is put on the protruding pillar 611 of the supporting arm 61. One end 622 of the second elastic element 62 is fixed to the supporting arm 61, while the other end 622 thereof abuts against the base 10, thereby providing a force for restoring the other end of the supporting arm 61 upwardly to its original position. In this way, the cover 30 can be lifted automatically once an initial force has been applied, and the lifted angle of the cover 30 can be limited. Via the above constitution, the external hard disk box having a cover-lifting means according to the present invention can be formed.

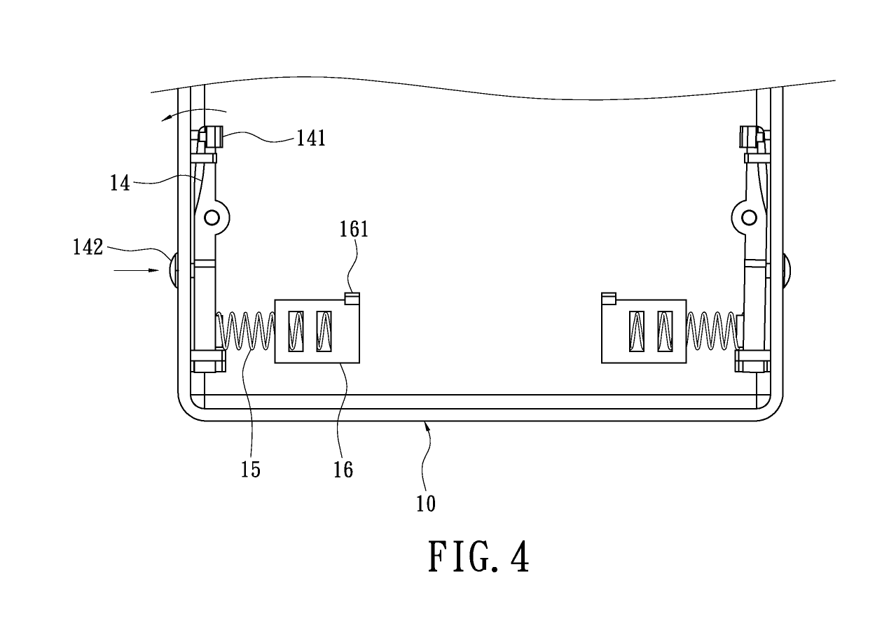

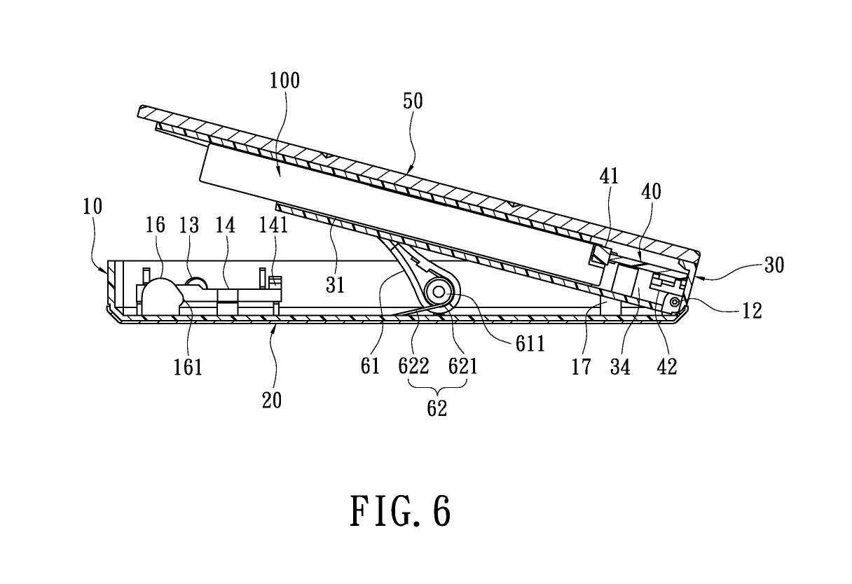

When the present invention is in use, the pair of operating portions 142 of the respective locking pieces 14 is pressed, and thereby drives the pair of first locking portions 141 to move. In this way, the locking between the pair first locking portions 141 and the pair second locking portions 38 can be released (also refer to the arrows in FIG. 4), so that the cover 30 can be lifted upwards to a predetermined angle and position via the elastic force exerted by the pair of second elastic elements 62 of the respective cover-ejecting structures 60 (FIGS. 5 and 6).

Please reference especially to FIGS. 5 and 6, but also in conjunction to FIGS. 1 and 2. When the user intends to mount a hard disk 100, the user only needs to insert the hard disk 100 into the hard disk accommodating portion 31 through the insertion hole 32 (FIG. 2) of the cover 30. Then, the user pushes the hard disk 100 rearwards, so that the connector 101 (FIG. 1) of the hard disk 100 and the hard disk connector 41 (FIG. 1) of the adapter circuit board 40 can be connected to each other, thereby achieving the electrical connection between the hard disk 100 and the adapter circuit board 40.

Thereafter, the cover 30 is covered downwards on the base 10. Via the cooperation of the pair of locking pieces 14 and the pair of first elastic elements 15, the pair of second locking portions 38 of the cover 30 can be locked to the pair of first locking portions 141, so that the cover 30 can be fixed on the base 10.

Furthermore, when the cover 30 is lifted upwards, since the hard disk 100 will elevate upwards along with the cover 30, the user can grip both side surfaces of the hard disk 100 via the pair of notches 33 (FIG. 2) of the cover 30. Therefore, it is more convenient and labor-saving to detach the hard disk 100 from the insertion hole 32 (FIG. 2) of the cover 30.

Alternatively, the present invention further includes a hard disk pressing structures 70 provided between the base 10 and the cover 30 (FIGS. 1 and 6). In the present embodiment, the hard disk pressing structures 70 comprises of two pushing blocks 16, but they are not limited thereto (i.e. there can be one or more pushing blocks 16). The two pushing blocks 16 are separately provided inside the base 10 near its front end. Each block 16 is provided with a pushing surface 161 on one side thereof near the hard disk accommodating portion 31. When the cover 30 is covered downwards, the pushing surface 161 of the pushing block 16 presses the front end surface of the hard disk 100, so that the hard disk 100 can move backwards and is electrically connected to the adapter circuit board 40.

Therefore, when the cover 30 is covered on the base 10, the hard disk 100 is electrically connected with the adapter circuit board 40 via the hard disk pressing structures 70.

Further, the present invention further includes a hard disk ejecting structures 80 between the base 10 and the cover 30 (FIGS. 1 and 6). In the present embodiment, the hard disk ejecting structures 80 comprises of two abutting blocks 17, but they are not limited thereto (i.e. there can be one or more abutting blocks 17). The two abutting blocks 17 are separately provided inside the base 10 adjacent to its rear end. Each abutting block 17 is provided with an abutting surface 171 on one side near the hard disk 100. The cover 30 is provided with a pair of through holes 39 (FIG. 2) that penetrate the bottom surface of the cover 30 and is in communication with the interior of the cover 30, so that the two abutting blocks 17 can be disposed in the through holes.

Therefore, when the cover 30 is lifted upwards from the base 10, the two abutting surfaces 171 of the two respective abutting blocks 17 exert a force to the rear end surface of the hard disk 100, so that the hard disk 100 can move away from the adapter circuit board 40, thereby helping the user to take out the hard disk 100 with less labor. Therefore, when the external hard disk box having a cover-lifting means according to the present invention is used, unlike prior art, it is unnecessary to detach the screws and then pull out the rails thereby mount or detach the hard disk 100. Thus, as long as the locking between the cover 30 and the base 10 is released, the cover 30 can be lifted upwards. In this way, the hard disk 100 can be mounted on or detached from the cover 30 directly. Thus, it is more convenient and labor-saving to use the present invention.

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. An external hard disk box having a cover-lifting means, comprising:
a hollow base;
a cover pivotally connected to the base in a liftable and closable manner, the cover being provided with a hard disk accommodating portion for accommodating a hard disk;
a first casing adhered to an outside surface of the base; and
a second casing adhered to an outside surface of the cover;
wherein when the cover is lifted, the hard disk is elevated along with the cover, so that a user can take out the hard disk.

2. The external hard disk box having a cover-lifting means according to claim 1, wherein the rear end of the base and the rear end of the cover are provided with a pair of first pivoting portions and a pair of second pivoting portions and they are respectively and pivotally connected to each other.

3. The external hard disk box having a cover-lifting means according to claim 2, wherein the front end of the cover is provided with an insertion hole that is in communication with the hard disk accommodating portion for allowing the hard disk to be inserted therein.

4. The external hard disk box having a cover-lifting means according to claim 1, wherein the base is provided with at least one locking piece and at least one first elastic element, one end of the locking piece is provided with a first locking portion, the other end of the locking piece is provided with an operating portion, the operating portion extends outside the base, the first elastic element abuts against one side of the locking piece, the cover is provided with a second locking portion corresponding to the first locking portion, the second locking portion is locked to the first locking portion when the cover is covered, thereby fixing the cover onto the base.

5. The external hard disk box having a cover-lifting means according to claim 4, wherein the second locking portion is formed by means of protruding outwards from one side of the cover.

6. The external hard disk box having a cover-lifting means according to claim 1, wherein the hard disk accommodating portion is an accommodating trough, and the accommodating trough is formed by means of recessing inwards from the front end of the cover.

7. The external hard disk box having a cover-lifting means according to claim 1, further comprising a pair of cover-ejecting structures, the cover-ejecting structures being provided between the base and the cover, so that the cover is lifted automatically to a predetermined angle.

8. The external hard disk box having a cover-lifting means according to claim 7, wherein the pair of cover-ejecting structures each comprises at least one supporting arm and at least one second elastic element, one end of the supporting arm is pivotally connected to the base, the other end of the supporting arm is pivotally connected to the cover, and the second elastic element is provided between the supporting arm and the base.

9. The external hard disk box having a cover-lifting means according to claim 8, wherein the second elastic element is a torsion spring.

10. The external hard disk box having a cover-lifting means according to claim 1, further comprising an adapter circuit board, and the adapter circuit board being provided in the cover.

11. The external hard disk box having a cover-lifting means according to claim 10, further comprising a hard disk pressing structures, the hard disk pressing structures being provided between the base and the cover, and when the cover is covered, the hard disk move backward and electrically connected to the adapter circuit board via the hard disk pressing structures.

12. The external hard disk box having a cover-lifting means according to claim 11, wherein the hard disk pressing structures comprises at least one pushing block provided inside the base and adjacent to its front end, the pushing block is provided with a pushing surface on one side near the hard disk accommodating portion.

13. The external hard disk box having a cover-lifting means according to claim 10, further comprising a hard disk ejecting structures, the hard disk ejecting structures being provided between the base and the cover, so that the hard disk is moved away from the adapter circuit board via the hard disk ejecting structures when the cover is lifted.

14. The external hard disk box having a cover-lifting means according to claim 13, wherein the hard disk ejecting structures comprises at least one abutting block provided inside the base, the abutting block is provided with an abutting surface on one side near the hard disk, and the cover is provided with through holes for allowing the abutting blocks to be disposed therein.

15. (canceled)

16. An external hard disk box having a cover-lifting means, comprising:
a hollow base;
a cover pivotally connected to the base in a liftable and closable manner, the cover being provided with a hard disk accommodating portion for accommodating a hard disk; and
a pair of cover-ejecting structures provided between the base and the cover, so that the cover is lifted automatically to a predetermined angle;
wherein when the cover is lifted, the hard disk is elevated along with the cover, so that a user can take out the hard disk.

17. An external hard disk box having a cover-lifting means, comprising:
a hollow base;
a cover pivotally connected to the base in a liftable and closable manner, the cover being provided with a hard disk accommodating portion for accommodating a hard disk; and
an adapter circuit board provided in the cover;
wherein when the cover is lifted, the hard disk is elevated along with the cover, so that a user can take out the hard disk.
